(19) United States
(12) Patent Application Publication
(10) Pub. No.: US 2026/0362876 A1
(43) Pub. Date: Nov. 12, 2026

(54) DISPLAY DEVICE

(71) Applicant: LX SEMICON CO., LTD., Daejeon (KR)

(72) Inventors: Jung Hoon KIM, Daejeon (KR); Ji Won LEE, Daejeon (KR)

(73) Assignee: LX SEMICON CO., LTD., Daejeon (KR)

(21) Appl. No.: 19/564,279

(22) Filed: Mar. 12, 2026

(30) Foreign Application Priority Data
Mar. 12, 2025 (KR) 10-2025-0031832

(51) Int. Cl. H10H 29/34; H10K 59/35; H10K 59/70

(52) U.S. Cl. CPC H10H 29/345; H10K 59/353; H10K 59/70

(57) ABSTRACT

The present specification discloses a display device. The disclosed display device includes a plurality of pixels that are disposed on a substrate and include a first to third sub-pixels of different colors, in which the first sub-pixel includes a first light-emitting element of the first color and a second light-emitting element of the first color, the second sub-pixel includes a third light-emitting element of a second color, and the third sub-pixel includes a fourth light-emitting element of a third color.

### CROSS-REFERENCE TO RELATED APPLICATION

This application claims priority to and the benefit of Korean Patent Application No. 10-2025-0031832, filed on March, 12, 2025, the disclosure of which is incorporated herein by reference in its entirety.

### BACKGROUND

### Field

The present specification relates to a display device.

### Discussion of Related Art

As a display device, an organic light emitting display (OLED) that emits light itself and a liquid crystal display (LCD) that requires a separate light source are known.

Recently, a display device including a light-emitting element (for example, a light emitting diode (LED)) has attracted much attention as a next-generation display device. Because the light-emitting element is made of an inorganic material, not an organic material, the light-emitting element has a fast light-up speed and excellent luminous efficiency and can display an image with high luminance compared to a liquid crystal display or an organic light emitting display.

In the case of a WOLED panel, to overcome reduction in light efficiency of a color filter (CF), a two or three-layered tandem structure has been developed and a micro lens array has been additionally applied. In the case of an RGB OLED panel, while no CF is used, a multi-layered tandem structure has been applied to achieve luminance improvement. However, such panels exhibit inferior characteristics to a micro LED panel in terms of lifetime, performance, and efficiency.

Further, the micro LED panel has been examined focusing on research and development due to costs and the absence of mass production technology. In particular, for the use of a micro LED, reduction in light efficiency should be improved in a micro structure. In the case of a red LED, reduction in efficiency and color quality due to an increase in non-light-emitting combination and change in peak wavelength may become a severe problem.

### SUMMARY

Embodiments of the present specification provide a display device capable of improving color quality of a micro LED in a low current density region and improving red micro LED light efficiency.

Embodiments of the present specification provide a display device capable of reducing power consumption in a high current density region compared to an OLED panel and improving luminance and lifetime of a display panel.

The problems addressed by the present disclosure are not limited to those described above, and other problems not described will be clearly understood by those skilled in the art from the following description.

A display device according to an embodiment of the present specification includes a plurality of pixels that are disposed on a substrate and include first to third sub-pixels of different colors, in which the first sub-pixel includes a first light-emitting element of a first color and a second light-emitting element of the first color, the second sub-pixel includes a third light-emitting element of a second color, and the third sub-pixel includes a fourth light-emitting element of a third color.

The first light-emitting element of the first color may include a red micro LED element, and the second light-emitting element of the first color may include a red OLED element.

The third light-emitting element of the second color may include a green micro LED element, and the fourth light-emitting element of the third color may include a blue micro LED element.

The first light-emitting element of the first color may include a green micro LED element, the second light-emitting element of the first color may include a green OLED element, the third light-emitting element of the second color may include a red micro LED element, and the fourth light-emitting element of the third color may include a blue micro LED element.

The first light-emitting element of the first color may include a blue micro LED element, the second light-emitting element of the first color may include a blue OLED element, the third light-emitting element of the second color may include a red micro LED element, and the fourth light-emitting element of the third color may include a green micro LED element.

The first light-emitting element of the first color and the second light-emitting element of the first color may be disposed to be stacked in a vertical direction.

A first cathode electrode of the light-emitting element and a second anode electrode of the second light-emitting element may be shared.

The first light-emitting element may include a first anode electrode connected to a first transistor provided on the substrate, a micro LED element disposed on the first anode electrode, and the first cathode electrode provided on the micro LED element, and the second light-emitting element may include the second anode electrode that is connected to a second transistor provided on the substrate and extends from the first cathode electrode, an OLED element disposed on the second anode electrode, and a second cathode electrode disposed on the OLED element.

The red micro LED element may be positioned in a high current density region, and the red OLED element may be positioned in a low current density region.

The first sub-pixel may include a first interval in which the micro LED element driven, a second interval in which the OLED element is driven, and a third interval in which the micro LED element and the OLED element are driven simultaneously.

The effects of the present disclosure are not limited to the effects described above, and other effects not described will be understood by those skilled in the art from the following description and the appended claims.

According to the embodiment of the present specification, it is possible to improve color quality of a micro LED element by applying an OLED in a low current density region.

According to the embodiment of the present specification, it is possible to improve light efficiency with an increase in no-radiative recombination because a surface recombination velocity of the red micro LED element is 10 times to 100 times higher than InGaN-based elements.

According to the embodiment of the present specification, it is possible to reduce current consumption, improve luminance, and improve lifetime by applying the red micro LED in a high current density region compared to when an OLED element is applied.

According to the embodiment of the present specification, because the OLED and the micro LED are different in light efficiency and RGB luminance characteristics, it is possible to secure expression consistency of a seamless panel in a luminance change interval by developing and applying hybrid-auto color calibration (ACC) technology such as a gamma LUT and a gamut mapping IP.

The effects of the present disclosure are not limited to the effects described above, and other effects not described will be understood by those skilled in the art from the following description and the appended claims.

### BRIEF DESCRIPTION OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a plan view of a display device according to an embodiment of the present specification;

FIG. 2 is a perspective view of the display device according to the embodiment of the present specification;

FIG. 3 is a circuit configuration diagram of the display device according to the embodiment of the present specification;

FIG. 4 is a cross-sectional view taken along line I-I′ of FIG. 1;

FIG. 5 is a circuit configuration diagram showing a driving state when a red OLED element is turned on and a red micro LED element is turned off in the display device according to the embodiment of the present specification;

FIG. 6 is a circuit configuration diagram showing a driving state when the red OLED element is turned off and the red micro LED element is turned on in the display device according to the embodiment of the present specification;

FIG. 7 is a driving state diagram of the red OLED element and the red micro LED element in the display device according to the embodiment of the present specification;

FIG. 8 is a diagram showing a use luminance interval of an OLED element and a use luminance interval of a micro LED element in the display device according to the embodiment of the present specification; and

FIG. 9 is a diagram showing a gamma look-up table in the display device according to the embodiment of the present specification.

### DETAILED DESCRIPTION OF EXEMPLARY EMBODIMENTS

The advantages and features of the present specification, and methods of achieving them will be apparent from the embodiments described in detail below in conjunction with the accompanying drawings. However, the present specification is not limited to the following embodiments disclosed herein, but may be implemented in various different forms; rather, the present embodiments are provided to make the disclosure of the present specification complete and to enable those skilled in the art to fully comprehend the scope of the present specification.

The shapes, sizes, proportions, angles, numbers, and the like of elements shown in the drawings to illustrate embodiments of the present specification are merely illustrative and are not intended to be limiting. Identical reference numerals may designate identical components throughout the description. Further, in describing the present specification, detailed descriptions of related known technologies may be omitted so as not to obscure the essence of the present specification. The terms such as “including,” “having,” and “consisting of” as used herein are generally intended to allow other components to be added unless the terms are used with the term “only.” References to components of a singular noun include the plural of that noun, unless specifically stated otherwise.

In the interpretation of components, they are construed to include margins of error, even if not explicitly stated.

When describing a positional relationship, for example, “on top of,” “above,” “below,” “next to,” or “adjacent to” describes the positional relationship of two parts, one or more other parts may be located between the two parts, unless “immediately,” “directly,” or “near to” is used.

When describing a temporal relationship, “after,” “subsequently to,” “following,” or, “before” describes a temporal antecedent or consequent relationship, which may not be continuous unless “immediately,” or “directly” is used.

The first, the second, and so on are used to describe various components, but these components are not limited by these terms. These terms are used only to distinguish one component from another. Therefore, a first component referred to below may be a second component within the technical spirit of the present specification.

Terms such as first, second, A, B, (a), or (b) may be used to describe elements of the embodiments of the present specification. Such terms are intended only to distinguish one component from another and are not intended to define the nature, sequence, order, or number of such components.

When a component is described as being “connected,” “coupled”, “accessed,” or “attached” to another component, it is to be understood that the component may be directly connected, coupled, accessed, or attached to the other component, but that there may also be other components interposed between the respective components which may be indirectly connected, coupled, accessed, or attached, unless specifically stated otherwise.

When a component is described as being “in contact” or “overlapping” with another component, it is to be understood that the component may be in direct contact or overlap with the other component, but other components may also be “interposed” between the these components, resulting in indirect contact or overlap, unless specifically stated otherwise.

It should be understood that the term “at least one” includes all possible combinations of one or more related components. For example, the meaning of “at least one of the first, second, and third components” may be understood to include not only the first, second, or third component, but also any combination of two or more of the first, second, and third components.

The terms “the first direction,” “the second direction,” “the third direction,” “the X-axis direction,” “the Y-axis direction,” and “the Z-axis direction” are not to be interpreted solely as a geometric relationship in which the relationship to one another is perpendicular, but may refer to a broader range of orientations in which the configurations of the present specification may function.

Each of the features of various embodiments of the present specification may be coupled or combined with one another in whole or in part, and may be technologically interlocked and operated in various ways, and each of the embodiments may be carried out independently or in conjunction with one another.

Hereinafter, various embodiments of the present specification will be described in detail with reference to the accompanying drawings.

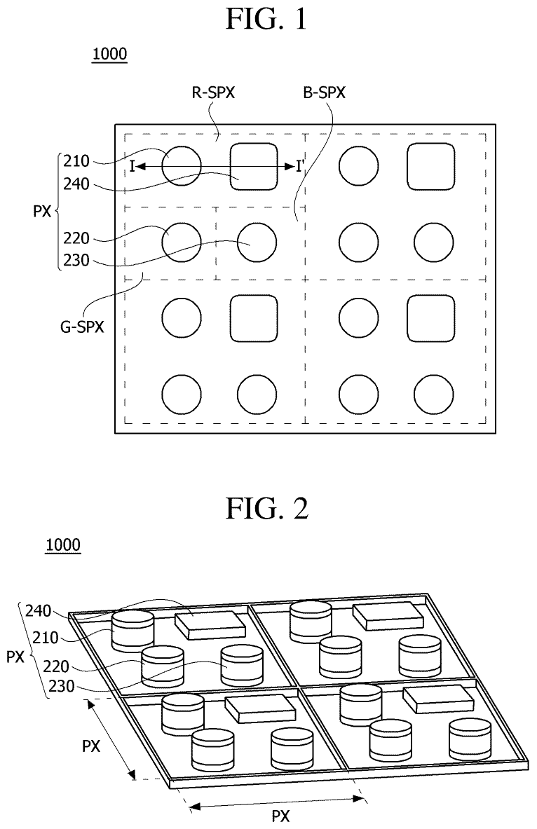

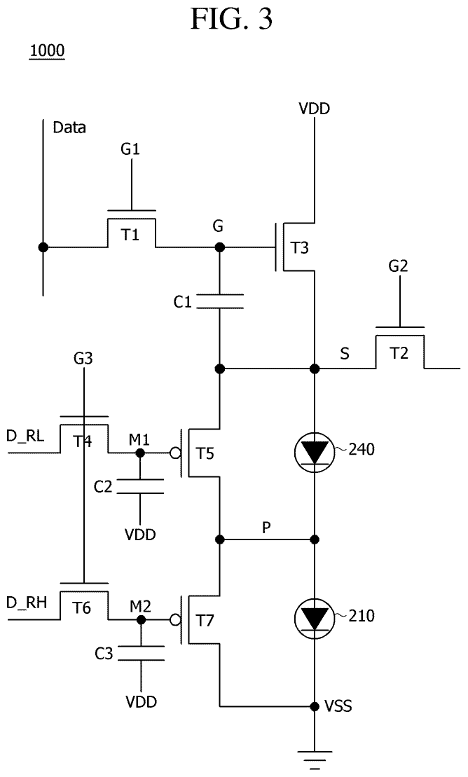

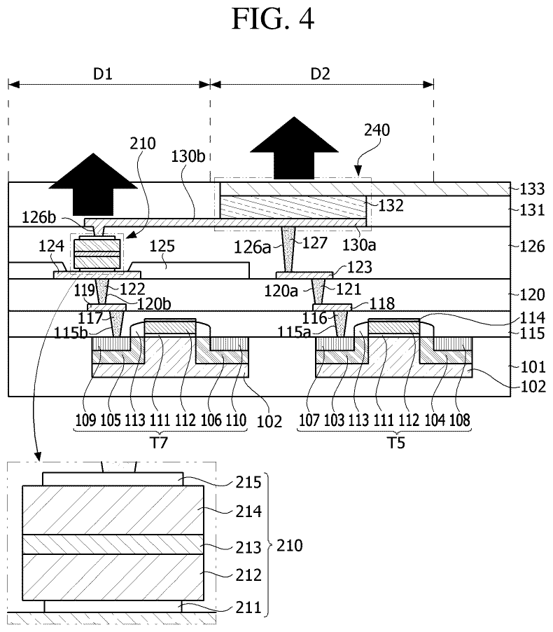

FIG. 1 is a plan view of a display device according to an embodiment of the present specification. FIG. 2 is a perspective view of the display device according to the embodiment of the present specification. FIG. 3 is a circuit configuration diagram of the display device according to the embodiment of the present specification. FIG. 4 is a cross-sectional view taken along line I-I′ of FIG. 1.

Referring to FIGS. 1 and 2, a display device 1000 according to the embodiment of the present specification may include a plurality of pixels PX.

Here, each of the plurality of pixels PX may include a red sub-pixel R-SPX, a green sub-pixel G-SPX, and a blue sub-pixel B-SPX disposed adjacent to each other in a horizontal direction.

The red sub-pixel R-SPX may include a first light-emitting element 210 of red a fourth light-emitting element 240 of red. The first light-emitting element 210 of red may be a red micro LED element, and the fourth light-emitting element 240 of red may be a red OLED element. However, embodiments of the present specification are not limited thereto.

The green sub-pixel G-SPX may include a second light-emitting element 220 for green. The second light-emitting element 220 for green may include a green micro LED element. However, embodiments of the present specification are not limited thereto. For example, the green sub-pixel G-SPX may include a green micro LED element and a green OLED element. In this case, the red sub-pixel R-SPX may be a red micro LED element, and the blue sub-pixel B-SPX may be a blue micro LED element.

The blue sub-pixel B-SPX may include a third light-emitting element 230 of blue The third light-emitting element 230 of blue may be a blue micro LED element. However, embodiments of the present specification are not limited thereto. For example, the blue sub-pixel B-SPX may include a blue micro LED element and a blue OLED element. In this case, the red sub-pixel R-SPX may be a red micro LED element, and the green sub-pixel G-SPX may be a green micro LED element.

Hereinafter, in the present specification, a case where the red sub-pixel R-SPX is composed of the first light-emitting element 210, which is a red micro LED element, and the fourth light-emitting element 240, which is a red OLED element, will be described as an example.

While a circuit diagram of the plurality of sub-pixels R-SPX, G-SPX, and B-SPX that compose the plurality of pixels PX in the display device 1000 according to the embodiment of the present specification may be made in various forms, in the present specification, a form in which seven transistors T1 to T7 and three capacitors C1 to C3 are provided as in FIG. 3 will be described.

Referring to FIG. 3, the display device 1000 according to the embodiment of th present specification may include a plurality of transistors T1 to T7 disposed on a substrate 101 and first and fourth light-emitting elements 210 and 240 that are connected to the plurality of transistors T1 to T7. However, embodiments of the present specification are not limited thereto. Here, description will be provided focusing on a circuit configuration of the first light-emitting element 210, which is a red micro LED element, and the fourth light-emitting element 240, which is a red OLED element, composing the red sub-pixel R-SPX among the red, green, and blue sub-pixels R-SPX, G-SPX, and B-SPX in each of the plurality of pixels PX.

Specifically, among the plurality of transistors T1 to T7, first to fourth and sixth transistors T1 to T4 and T6 may be switching transistors, and fifth and seventh transistors T5 and T7 may be driving transistors. However, embodiments of the present specification are not limited thereto.

Among the switching transistors T1 to T4 and T6, a first switching transistor may include a gate connected to a first gate line G1, a source connected to a data line data, and a drain connected to a first node G.

The first node G may be connected to a gate of a third switching transistor T3 and one end of a first capacitor C1.

A second switching transistor T2 may include a gate connected to a second gate line G2 and a source connected to a second node S. In this case, the second node S may be connected to the other end of the first capacitor C1, a drain of a fifth driving transistor T5, and one end of the fourth light-emitting element 240.

A third switching transistor T3 may include a gate connected to the first node G be connected to the drain of the first switching transistor T1 and the first capacitor C1 and a source connected to a high-potential power supply voltage VDD.

A fourth switching transistor T4 may include a gate connected to a third gate line G3 and a source connected to a first data input signal D_RL for driving the fourth light-emitting element 240, which is a red OLED element. The fourth switching transistor T4 may further include a drain connected to a third node M1 to be connected to a gate of the fifth driving transistor T5 and one end of the second capacitor C2. The other end of the second capacitor C2 may be connected to the high-potential power supply voltage VDD.

The fifth driving transistor T5 may include the drain connected to one end of th first capacitor C1 and the second node S, and a source connected to a fourth node P. The fourth node P may be connected to the other end of the fourth light-emitting element 240 and one end of the first light-emitting element 210, and may be connected between the fifth driving transistor T5 and a seventh driving transistor T7.

The sixth switching transistor T6 may include a gate connected to the third gate line G3 and a source connected to a second data input signal D_RH for driving the first light-emitting element 210, which is a red micro LED element. The sixth switching transistor T6 may further include a drain connected to the fifth node M2 to be connected to a gate of the seventh driving transistor T7 and one end of the third capacitor C3.

The seventh driving transistor T7 may include a source connected to a low-potential power supply voltage VSS and a drain connected to the fourth node P and the fifth driving transistor T5.

The first light-emitting element 210, which is a red micro LED element, may include one end connected to the source of the seventh driving transistor T7 and the low-potential power supply voltage VSS, and the other end connected to the drain of the seventh driving transistor T7 and the fourth node P.

The fourth light-emitting element 240, which is a red OLED element, may include one end connected to the second node S to which the drain of the fifth driving transistor T5 is connected and the other end connected to the fourth node P.

The first capacitor C1 may be connected to the first node G, the fifth driving transistor T5, and the second node S.

The second capacitor C2 may be connected to the third node M1 and the high-potential power supply voltage VDD.

The third capacitor C3 may be connected to the fifth node M2 and the high-potential power supply voltage VDD.

Referring to FIG. 4, in the display device 1000 according to the embodiment of the present specification, the fifth driving transistor T5 and the seventh driving transistor T7 may be disposed on the substrate 101. The first light-emitting element 210 may be disposed on the seventh driving transistor T7. The first light-emitting element 210 may be connected to

### The Seventh Driving Transistor T7.

The fourth light-emitting element 240 may be disposed on the fifth driving transistor T5. The fourth light-emitting element 240 may be connected to the fifth driving transistor T5.

Specifically, the first light-emitting element 210 may be connected to the seventh driving transistor T7, and the fourth light-emitting element 240 may be connected to the fifth driving transistor T5. The first light-emitting element 210 may be a red micro LED element, and the fourth light-emitting element 240 may be a red OLED element.

The first light-emitting element 210 may be positioned in a high current density region D1, and the fourth light-emitting element 240 may be positioned in a low current density region D2. For example, when a luminance interval is divided into 0 to 255 grayscales, a red micro LED element may be disposed in the high current density region, and a red OLED element may be disposed in the low current density region.

Here, the high current density region may mean a high luminance region, and th low current density region may mean a low luminance region.

Accordingly, the display device according to the embodiment of the present specification may have a structure in which the first light-emitting element 210, which is a red micro LED element, and the fourth light-emitting element 240, which is a red OLED element, are disposed in the red sub-pixel R-SPX in a vertical direction instead of being disposed sideway, and electrodes are shared and used. For example, though will be described below, a first cathode electrode 130b of the first light-emitting element 210 and a fourth anode electrode 130a of the fourth light-emitting element 240 may be shared and used.

While the first light-emitting element 210 and the fourth light-emitting element 240 may be used as a stacked structure, because the lifetime and performance of the fourth light-emitting element 240 may be deteriorated, a stacked structure form may be shown on a side surface and a sideway arrangement structure form may be shown on an upper surface.

In the substrate 101 in which the plurality of transistors T1 to T7 are disposed, first conduction type well regions 102 may be formed. Gates 112 may be formed on the substrate 101 in which the first conduction type well regions 102 are provided. The gates 112 may be formed of a conductive material, for example, polysilicon. Here, the first conduction type refers to an N type.

A gate insulating film 111 may be disposed between the gate 112 and the first conduction type well region 102.

Second conduction type low concentration regions 103, 104, 105, and 106 may be formed in the first conduction type well regions 102 below both sides of the gates 112. The second conduction type refers to a P type.

In the second conduction type low concentration regions 103, 104, 105, and 106, second conduction type drain regions 107 and 109 and second conduction type source regions 108 and 110 may be formed.

A sidewall insulating film 113 may be formed on both side surfaces of the gates 112. The gate 112, the first conduction type well region 102, the second conduction type drain region 107, and the second conduction type source region 108 may compose the fifth driving transistor T5. The gate 112, the first conduction type well region 102, the second conduction type drain region 109, and the second conduction type source region 110 may compose the seventh driving transistor T7. However, embodiments of the present specification are not limited thereto. For example, through not shown in the drawing, each of the first to fourth transistors T1 to T4 and the sixth transistor T6 may include the gate 112, the first conduction type well region 102, the second conduction type drain region 107, and the second conduction type source region 108.

A hard mask insulating film 114 may be formed on an upper surface of the gate 112. The hard mask insulating film 114 may be applied for gate etching, and may be formed of a silicon oxide film, a silicon nitride film, or the like.

A first insulating film 115 that covers the gate 112, the sidewall insulating film 113, and the hard mask insulating film 114 may be formed on the substrate 101.

In the first insulating film 115, first and second contact holes 115a and 115b that expose the second conduction type drain regions 107 and 109, respectively, may be formed. Further, in the first insulating film 115, first and second contact plugs 116 and 117 that are in contact with the second conduction type drain regions 107 and 109 via the first and second contact holes 115a and 115b, respectively, may be formed.

On the first insulating film 115, first and second connection wires 118 and 119 that are connected to the first and second contact plugs 116 and 117, respectively, may be formed. However, embodiments of the present specification are not limited thereto. For example, the first and second connection wires 118 and 119 may be made of the same material layer as the first and second contact plugs 116 and 117.

On the first insulating film 115, a second insulating film 120 that covers the first and second connection wires 118 and 119 may be disposed.

In the second insulating film 120, second contact holes 120 a and 120 b that expose the first and second connection wires 118 and 119, respectively, may be formed. Further, in the second insulating film 120, third and fourth contact plugs 121 and 122) that are in contact with the first and second connection wires 118 and 119 via the second contact holes 120a and 120b, respectively, may be formed.

On the second insulating film 120, a third connection wire 123 and a first anode electrode 124 that are connected to the third and fourth contact plugs 121 and 122, respectively, may be formed. However, embodiments of the present specification are not limited thereto. For example, the third connection wire 123 and the first anode electrode 124 may be made of the same material layer as the third and fourth contact plugs 121 and 122.

The first anode electrode 124 may be a component for supplying holes to a first light-emitting layer 213 described below, and may be formed of a conductive material having a high work function. The first anode electrode 124 may be a transparent conductive layer formed of a transparent conductive oxide (TCO). For example, the first anode electrode 124 may be formed of one or more selected from transparent conductive oxides such as indium tin oxide (ITO), indium zinc oxide (IZO), indium tin zinc oxide (ITZO), tin oxide (SnO2), zinc oxide (ZnO), indium copper oxide (ICO), and Al-doped ZnO (AZO), but embodiments of the present specification are not limited thereto.

When the display device 1000 is driven by a tip emission method, the first anode electrode 124 may further include a reflective pattern for reflecting light emitted from the first light-emitting layer 213 toward the first cathode electrode 130b.

On the second insulating film 120, banks 125 that cover edge portions of the fir anode electrode 124 may be formed. The banks 125 may be made of an insulating material to insulate the first anode electrode 124. The banks 125 may be composed of black banks having high light absorption to prevent color mixture between adjacent sub-pixels. For example, the banks 125 may be made of polyimide resin, acryl resin, or benzocyclobutene resin, but embodiments of the present specification are not limited thereto.

A first light-emitting element 210 may be disposed on the first anode electrode 1 between the banks 125. The first light-emitting element 210 may be a red micro LED element. The first light-emitting element 210 may be applied to the high current density region D1.

In this way, in the present specification, it is possible to expect reduction in power consumption, improvement of luminance, and improvement of luminance compared to an OLED element by disposing the first light-emitting element 210, which is a red micro LED element, in the high current density region.

Here, the first light-emitting element 210 may include a first-first conduction type semiconductor layer 212, a first light-emitting layer 213 disposed on the first-first conduction type semiconductor layer 212, and a first-second conduction type semiconductor layer 214 disposed on the first light-emitting layer 213. A first-first contact electrode 211 may be disposed below the first-first conduction type semiconductor layer 212, and a first-second contact electrode 215 may be disposed above the first-second conduction type semiconductor layer 214.

A first light-emitting element 210 may be formed on a silicon wafer using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering.

The first-first conduction type semiconductor layer 212 may be implemented as a compound semiconductor such as a III-V group or a II-VI group, and may be doped with a first dopant. The first-first conduction type semiconductor layer 212 may be formed of one or more of a semiconductor material having a compositional formula of Alx1Iny1Ga(1-x1-y1)N (0≤x 1≤1, 0≤y 1≤1 , 0≤x 1+y1≤1), InAlGaN, AlGaAs, GaP, GaAs, GaAsP, and AlGaInP, but embodiments of the present specification are not limited thereto. When the first dopant is an n-type dopant such as Si, Ge, Sn, Se, or Te, the first-first conduction type semiconductor layer 212 may be an n-type nitride semiconductor layer. Meanwhile, when the first dopant is a p-type dopant, the first-first conduction type semiconductor layer 212 may be a p-type nitride semiconductor layer.

The first light-emitting layer 213 is a layer in which electrons (holes) injected v the first-first conduction type semiconductor layer 212 meet holes (or electrons) injected via the first-second conduction type semiconductor layer 214. The first light-emitting layer 213 may transit a low energy potential according to recombination of electrons and holes, and may generate red light having a corresponding wavelength.

The first light-emitting layer 213 may have one structure of a single well structure, a multi well structure, a single quantum well structure, a multi quantum well (MQW) structure, a quantum dot structure, or a quantum wire structure, but the structure of the first light-emitting layer 213 is not limited thereto. The first light-emitting layer 213 may generate light in a visible light wavelength range. For example, the first light-emitting layer 213 may out light in a wavelength range of one of blue, green, and red. For example, a case where the first light-emitting layer 213 in the present specification outputs red light in a red wavelength range is illustrated.

The first-second conduction type semiconductor layer 214 may be disposed on the first light-emitting layer 213. The first-second conduction type semiconductor layer 214 may be implemented as a compound semiconductor such as a III-V group or a II-VI group, and the first-second conduction type semiconductor layer 214 may be doped with a second dopant. The first-second conduction type semiconductor layer 214 may be formed of a material selected from a semiconductor material having a compositional formula of Inx2Aly2Ga1-x2-y2N (0≤x2≤1, 0≤y2≤1, 0≤x2+y2≤1), AlInN, AlGaAs, GaP, GaAs, GaAsP, and AlGaInP. When the second dopant is a p-type dopant such as Mg, Zn, Ca, Sr, or Ba, the first-second conduction type semiconductor layer 214 doped with the second dopant may be a p-type semiconductor layer. When the second dopant is an n-type dopant, the first-second conduction type semiconductor layer 214 may be an n-type nitride semiconductor layer.

A first-second contact electrode 215 disposed on the first-second conduction type semiconductor layer 214 and a third insulating film 126 that covers the third connection wire 123 may be disposed above the second insulating film 120.

In the third insulating film 126, fifth and sixth contact holes 126a and 126b that expose the first-second contact electrode 215 and the third connection wire 123 on the first light-emitting element 210, respectively, may be formed.

A fifth contact plug 127 may be formed in the fifth contact hole 126a positioned the low current density region D2.

A first cathode electrode 130b that is connected to the first-second contact electrode 215 of the first light-emitting element 210 and the third connection wire 123 via the sixth contact hole 126b and the fifth contact plug 127, respectively, may be formed. In this case, the first cathode electrode 130b may be applied as a fourth anode electrode 130a of a fourth light-emitting element 240 described below.

A fourth insulating film 131 that covers a portion excluding a portion corresponding to the fourth light-emitting element 240 in the first cathode electrode 130b may be disposed on the third insulating film 126.

A fourth light-emitting layer 132 may be disposed on the exposed fourth anode electrode 130a. Though not shown in the drawing, the fourth light-emitting layer 132 may further include some of a hole injection layer, a hole transport layer, an electron transport layer, and an electron injection layer.

A fourth cathode electrode 133 that is in contact with the fourth light-emitting layer 132 may be disposed on the fourth insulating film 131.

The fourth anode electrode 130a may be a component for supplying holes to the fourth light-emitting layer 132 and may be formed of a conductive material having a high work function. The fourth cathode electrode 133 may be a transparent conductive layer formed of a transparent conductive oxide (TCO). For example, the fourth cathode electrode 133 may be formed of one or more of transparent conductive oxides such as indium tin oxide (ITO), indium zinc oxide (IZO), indium tin zinc oxide (ITZO), tine oxide (SnO2), zinc oxide (ZnO), indium copper oxide (ICO), and Al-doped ZnO (AZO), but embodiments of the present specification are not limited thereto.

Accordingly, the fourth light-emitting element 240 may include the fourth anode electrode 130a that is also used as the first cathode electrode 130b of the first light-emitting element 210, the fourth light-emitting layer 132, and the fourth cathode electrode 133. The fourth light-emitting element 240 may be an OLED element. The red OLED element that is the fourth light-emitting element 240 may be applied to the low current density region D2.

In this way, the first light-emitting element 210, which is a red micro LED element, and the fourth light-emitting element 240, which is a red OLED element, may be disposed in the red sub-pixel R-SPX.

Therefore, according to the embodiment of the present specification, by disposing the fourth light-emitting element 240, which is an OLED element, in the low current density region D2, it is possible to improve a color quality deterioration phenomenon that may be caused by a peak wavelength shift likely to occur in the first light-emitting element 210, which is an InGaN-based micro LED element.

According to the embodiment of the present specification, because the surface recombination velocity of the first light-emitting element 210, which is an AlGaAs or AlGaInP-based red micro LED element, is 10 times to 100 times higher than InGaN, it is possible to improve light efficiency deterioration due to an increase in no-radiative recombination.

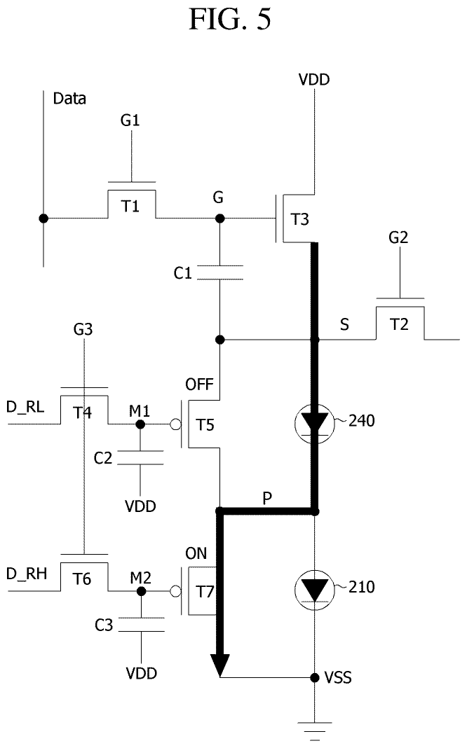

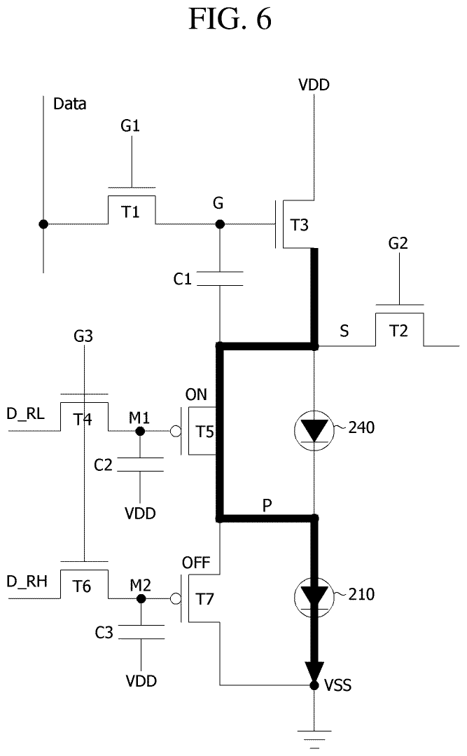

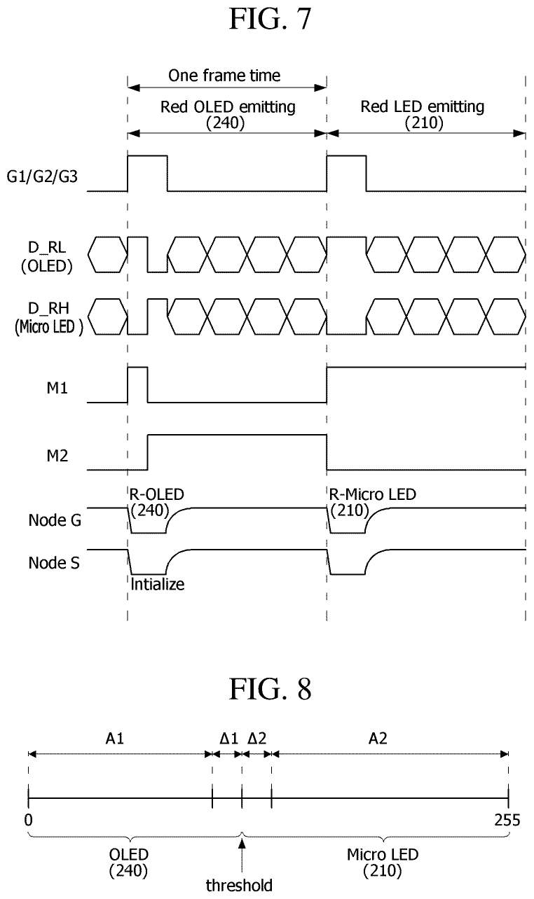

FIG. 5 is a circuit configuration diagram showing a driving state when a red OLED element is turned on and a red micro LED element is turned off in the display device according to the embodiment of the present specification. FIG. 6 is a circuit configuration diagram showing a driving state when the red OLED element is turned off and the red micro LED element is turned on in the display device according to the embodiment of the present specification. FIG. 7 is a driving state diagram of the red OLED element and the red micro LED element in the display device according to the embodiment of the present specification.

Referring to FIGS. 5 and 7, a state in which the fourth light-emitting element 240, which is a red OLED element, is turned on will be described. First, a high gate voltage may be applied to the first, second, and third gate lines G1, G2, and G3. Further, because the high gate voltage is applied to the gate of the fourth switching transistor T4, and the first data input signal D_RL is maintained at a low gate voltage, the fifth driving transistor T5 may be turned on.

On the other hand, because the high gate voltage is applied to the gate of the sixth switching transistor T6, and the second data input signal D_RH is maintained at the high gate voltage, the seventh driving transistor T7 may be turned off. Accordingly, the second node S and the fourth node P may be reset and initialized.

Subsequently, signals from the first to third gate lines G1, G2, and G3 may be maintained at the high gate voltage (HVG). In a state in which the high gate voltage (HVG) is applied to the gate of the fourth switching transistor T4, and the first data input signal D_RL for driving the fourth light-emitting element 240, which is a red OLED element, is maintained at the high gate voltage, the fifth driving transistor T5 may be turned off.

On the other hand, in a state in which the high gate voltage is applied to the gate of the sixth switching transistor T6, and the second data input signal D_RH for driving the first light-emitting element 210, which is a red micro LED element, is maintained at the low gate voltage, the fourth node P may be maintained at the same potential (w/VSS), and accordingly, the seventh driving transistor T7 may be turned on completely.

Subsequently, the signals of the first to third gate lines G1, G2, and G3 may be maintained at the low gate voltage until the fourth light-emitting element 240, which is a red OLED element, ends light emission. That is, the third node M1 may be maintained in a state in which the high gate voltage is applied, and the fifth node M2 may be maintained in a state in which the low gate voltage is applied.

In this way, because the gate of the fourth switching transistor T4 and the first data input signal D_RL are maintained at the high gate voltage, the fifth driving transistor T5 may be turned off. Further, in a state in which the high gate voltage is applied to the gate of the sixth switching transistor T6, because the second data input signal D_RH is maintained at the low gate voltage, the seventh driving transistor T7 may be turned on.

Accordingly, a signal is applied to the fourth light-emitting element 240, which a red OLED element, and the fourth light-emitting element 240 may be turned on.

Referring to FIGS. 6 and 7, a state in which the first light-emitting element 210 which is a red micro LED element, will be described as follows.

First, the high gate voltage may be applied to the first, second, and third gate lines G1, G2, and G3. Further, because the high gate voltage is applied to the gate of the fourth switching transistor T4, and the first data input signal D_RL is maintained at the low gate voltage, the fifth driving transistor T5 may be turned on.

On the other hand, because the high gate voltage is applied to the gate of the sixth switching transistor T6, and the second data input signal D_RH is maintained at the high gate voltage, the seventh driving transistor T7 may be turned off. Accordingly, the second node S and the fourth node P may be reset and initialized.

Subsequently, the signals from the first to third gate lines G1, G2, and G3 may be maintained at the high gate voltage (HVG). Further, in a state in which the high gate voltage (HVG) is applied to the gate of the fourth switching transistor T4, and the first data input signal D_RL for driving the fourth light-emitting element 240, which is a red OLED element, is maintained at the low gate voltage, the fifth driving transistor T5 may be turned on.

On the other hand, in a state in which the high gate voltage is applied to the gate of the sixth switching transistor T6, and the second data input signal D_RH for driving the first light-emitting element 210, which is a red micro LED element, is maintained at the high gate voltage, the fourth node P may be maintained at the same potential (w/VSS), and accordingly, the fifth driving transistor T5 may be turned on completely.

Subsequently, the signals of the first to third gate lines G1, G2, and G3 may be maintained at the low gate voltage until the first light-emitting element 210, which is a red micro LED element, ends light emission. That is, the third node M1 may be maintained in a state in which the log gate voltage is applied, and the fifth node M2 may be maintained in a state in which the high gate voltage is applied.

In this way, in a state in which the high gate voltage is applied to the gate of the fourth switching transistor T4, and the first data input signal D_RL is maintained at the low gate voltage, the fifth driving transistor T5 may be turned on. On the other hand, because the high gate voltage is applied to the gate of the sixth switching transistor T6 and the second data input signal D_RH, the seventh driving transistor T7 may be turned off.

Accordingly, because no signal is applied to the fourth light-emitting element 240, which is a red OLED element, and a signal is applied to the first light-emitting element 210 that is a red micro LED element, the first light-emitting element 210 may be turned on.

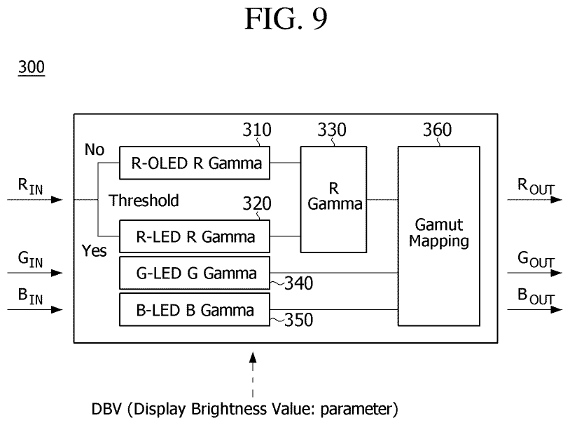

FIG. 8 is a diagram showing a use luminance interval of an OLED element and a use luminance interval of a micro LED element in the display device according to the embodiment of the present specification. FIG. 9 is a diagram showing a gamma look-up table in the display device according to the embodiment of the present specification.

Referring to FIG. 8, in the display device according to the embodiment of the present specification, a luminance interval may include a first luminance interval A1 in which the OLED element is used and a second luminance interval A2 in which the micro LED element is used.

Here, the first luminance interval A1 in which the OLED element is used may be a range of “0 to first luminance change interval (threshold−Δ1)”.

The second luminance interval A2 in which the micro LED element is used may be a range of “second luminance change interval (threshold+Δ2) to 255”.

In this way, by driving the micro LED element and the OLED element simultaneously in a simultaneous driving interval (for example, Δ1+Δ2) of the micro LED element, which is the first light-emitting element 210, and the OLED element, which is the fourth light-emitting element 240, it is possible to compensate for luminance and color together. In this case, auto luminescence and color calibration (ALCC) image quality compensation technology can be applied in an interval in which the micro LED element and the OLED element are driven simultaneously, for example, in the luminance change interval.

Referring to FIG. 9, in the display device according to the embodiment of the present specification, because the micro LED element and the OLED element are different in gamma luminance characteristic and color luminance characteristic, a separate gamma look-up table and a gamut mapping IP may be required in the interval in which the micro LED element and the OLED element are driven simultaneously, for example, in the luminance change interval.

Referring to FIG. 9, a look-up table (LUT) 300 may include a red OLED gamma R-OLED Gamma 310, a threshold, and a red LED gamma R-LED Gamma 320 to which a red signal RIN is input. The red OLED gamma R-OLED Gamma 310, the threshold, and the red LED gamma R-LED Gamma 320 may be connected to a red gamma R Gamma 330.

Further, the look-up table 300 may include a green LED gamma G-LED Gamma 340 to which a green signal GIN is input and a blue LED gamma B-LED Gamma 350 to which a blue signal BIN is input.

The red R Gamma 330, the green LED gamma G-LED Gamma 340, and the blue LED gamma B-LED Gamma 350 may be connected to color gamut correction (gamut mapping, 360).

Further, color and luminance may be corrected through the color gamut correction 360 of the look-up table 300 and may be output as red light, green light, and blue light.

In this way, to achieve a seamless display device in the luminance change interval, that is, in the simultaneous driving region between the first light-emitting element 210, which is a micro LED element, and the fourth light-emitting element 240, which is an OLED element, hybrid auto luminescence and color calibration (ALCC) technology for correcting consistent luminance and color may be applied.

α-blending and fusion algorithm for seamless change in the first luminance change interval (threshold−Δ1) and the second luminance change interval (threshold+Δ2) may be applied.

For example, in α-blending (linear), C (red luminance) may be α×A (OLED)+(1−α)×B (micro LED).

Further, in the fusion algorithm (non-linear), C (red luminance) may be f(A: OLED) 33 g(B: micro LED).

As above, according to the embodiment of the present specification, it is possible to improve color quality of the micro LED element by applying the OLED element in the low current density region.

According to the embodiment of the present specification, because the surface recombination velocity of the red micro LED element is 10 times to 100 times higher than InGaN-based elements, it is possible to improve light efficiency with an increase in no-radiative recombination.

According to the embodiment of the present specification, it is possible to reduce current consumption, improve luminance, and improve lifetime by applying the red micro LED in a high current density region compared to when an OLED element is applied.

According to the embodiment of the present specification, because the micro LED element and the OLED element are different in light efficiency and RGB luminance characteristics, it is possible to secure expression consistency of a seamless panel in the luminance change interval by developing and applying hybrid-auto color calibration (ACC) technology such as the gamma look-up table (gamma LUT) and the gamut mapping IP in the simultaneous driving interval of the micro LED element and the OLED element.

Accordingly, the embodiments disclosed herein are provided for illustrative purposes and are not intended to limit the technical concept of the present specification, and the scope of the technical concept of the present specification is not limited to these embodiments.

Therefore, it should be understood that the embodiments described above are illustrative in all aspects and are not intended to be limiting.

The scope of protection of the present disclosure should be construed on the basis of the following claims, and all technical concepts within the equivalent scope thereof should be construed as falling within the scope of the present invention.

### List of Reference Numbers

1000: Display device
101: Substrate
102: First conduction type well region
103, 104, 105, 106: Second conduction type low concentration region
107, 109: Second conduction type drain region
108, 110: Second conduction type source region
111: Gate insulating film
113: Sidewall insulating film
114: Hard mask insulating film
115: First insulating film
116: First contact plug
117: Second contact plug
118: First connection wire
119: Second connection wire
120: Second insulating film
121: Third contact plug
122: Fourth contact plug
123: Third connection wire
124: First anode electrode
125: Bank
126: Third insulating film
127: Fifth contact plug
130a: Fourth anode electrode
130b: First cathode electrode
131: Fourth insulating film
132: Fourth light-emitting layer
133: Fourth cathode electrode
210: First light-emitting element
211: First contact electrode
212: First-first conduction type semiconductor layer
213: First light-emitting layer
214: First-second conduction type semiconductor layer
215: First-second contact electrode
220: Second light-emitting element
230: Third light-emitting element
240: Fourth light-emitting element
300: Look-up table
310: Red OLED gamma
320: Red LED gamma
330: Red gamma
340: Green LED gamma
350: Blue LED gamma
360: Gamut mapping
D1: High current density region
D2: Low current density region
VDD: High-potential power supply voltage
VSS: Low-potential power supply voltage

What is claimed is:

1. A display device comprising:
a plurality of pixels that are disposed on a substrate and include first to third sub-pixels of different colors,
wherein the first sub-pixel includes a first light-emitting element of a first color and a second light-emitting element of the first color,
the second sub-pixel includes a third light-emitting element of a second color, and
the third sub-pixel includes a fourth light-emitting element of a third color.

2. The display device according to claim 1, wherein the first light-emitting element of the first color includes a red micro LED element, and the second light-emitting element of the first color includes a red OLED element.

3. The display device according to claim 2, wherein the third light-emitting element of the second color includes a green micro LED element, and the fourth light-emitting element of the third color includes a blue micro LED element.

4. The display device according to claim 1, wherein the first light-emitting element of the first color includes a green micro LED element, the second light-emitting element of the first color includes a green OLED element, the third light-emitting element of the second color includes a red micro LED element, and the fourth light-emitting element of the third color includes a blue micro LED element.

5. The display device according to claim 1, wherein the first light-emitting element of the first color includes a blue micro LED element, the second light-emitting element of the first color includes a blue OLED element, the third light-emitting element of the second color includes a red micro LED element, and the fourth light-emitting element of the third color includes a green micro LED element.

6. The display device according to claim 1, wherein the first light-emitting element of the first color and the second light-emitting element of the first color are disposed to be stacked in a vertical direction.

7. The display device according to claim 1, wherein a first cathode electrode of the first light-emitting element and a second anode electrode of the second light-emitting element are shared.

8. The display device according to claim 7, wherein:
the first light-emitting element includes a first anode electrode connected to a first transistor provided on the substrate, a micro LED element disposed on the first anode electrode, and a first cathode electrode provided on the micro LED element; and
the second light-emitting element includes a second anode electrode that is connected to a second transistor provided on the substrate and extends from the first cathode electrode, an OLED element disposed on the second anode electrode, and a second cathode electrode disposed on the OLED element.

9. The display device according to claim 2, wherein the red micro LED element is positioned in a high current density region, and the red OLED element is positioned in a low current density region.

10. The display device according to claim 2, wherein the first sub-pixel includes a first interval in which the micro LED element is driven, a second interval in which the OLED element is driven, and a third interval in which the micro LED element and the OLED element are driven simultaneously.

11. The display device according to claim 10, wherein a look-up table and gamut mapping are applied in the third interval.
